(19) United States
(12) Patent Application Publication
(10) Pub. No.: US 2019/0279954 A1
(43) Pub. Date: Sep. 12, 2019

(54) MICROELECTRONIC DEVICE STACK HAVING A GROUND SHIELDING LAYER

(71) Applicant: Intel Corporation, Santa Clara, CA (US)

(72) Inventors: Min-Tih Lai, Orangevale, CA (US); Florence Pon, Folsom, CA (US)

(73) Assignee: Intel Corporation, Santa Clara, CA (US)

(21) Appl. No.: 16/346,438

(22) PCT Filed: Dec. 1, 2016
(86) PCT No.: PCT/US16/64422

§ 371 Date: Apr. 30, 2019

(51) Int. Cl. H01L 23/00; H01L 23/552; H01L 25/065; H01L 25/07

(52) U.S. Cl. CPC H01L 24/24; H01L 23/552; H01L 24/49; H01L 25/065; H01L 25/07; H01L 24/33; H01L 2924/14; H01L 2224/24145; H01L 2224/32145; H01L 2224/32225; H01L 2224/48145; H01L 2224/73265; H01L 2224/04042

(57) ABSTRACT

A microelectronic device may be formed having at least one microelectronic die attached to a microelectronic substrate, wherein a ground shielding layer is formed over the microelectronic die and the microelectronic substrate. In one embodiment, both the microelectronic substrate and the first microelectronic die may have a signal bond pad and a ground bond pad. A bond wire may be used to form a connection between the microelectronic substrate signal bond pad and the first microelectronic die signal bond pad. A dielectric material layer may be formed on the microelectronic substrate and the first microelectronic die, and an electrically conductive material layer may be formed on the dielectric material layer, wherein the electrically conductive material layer extends through openings in the dielectric material layer to contact the microelectronic substrate ground bond pad and the first microelectronic die ground bond pad.

### TECHNICAL FIELD

Embodiments of the present description generally relate to the field of microelectronic packaging, and, more particularly, to a microelectronic device stack having a ground shielding layer.

### BACKGROUND

The microelectronic industry is continually striving to produce ever faster, smaller, and thinner microelectronic packages for use in various electronic products, including, but not limited to, computer server products and portable products, such as wearable microelectronic systems, portable computers, electronic tablets, cellular phones, digital cameras, and the like.

One way to achieve these goals is by increasing integration density, such as by stacking components within the microelectronic package. One stacking method may comprise a method typically used in NAND memory die stacking, wherein a plurality of bond pads are formed along one edge of each of the NAND memory dice. The NAND memory dice are stacked on a microelectronic substrate in a staggered or zig-zag configuration to allow access to the bond pads. Bond wires are then used to form electrical connections between the bond pads on various NAND memory dice and/or between the NAND memory dice and the microelectronic substrate. However, adjacent bond wires may induce and/or experience crosstalk, wherein current changes in one bond wire creates a magnetic field that induces current in adjacent wires. Furthermore, the wire bonds do not have a reference plane, which may result in a lack of impedance control (i.e. a discontinuity that creates signal noise).

Another stacking method may comprise the use of through-silicon vias wherein signal lines are formed in and through the stacked NAND memory dice to form connections therebetween, as will be understood to those skilled in the art. Through-silicon vias allow for very short conductor paths between the NAND memory dice and the microelectronic substrate, and longest distance for a transmission line to a corresponding wirebond pad location within each NAND memory die may be a fraction of the length of the NAND memory die. However, the use of through-silicon vias requires an increased number of expensive wafer level processing steps, and may cause reliability issues from copper processing temperature, volume expansion during annealing, and ion migration.

Therefore, there is a need to develop novel microelectronic die stacking configurations and designs to reduce cross-talk and improve reliability.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 illustrates an oblique view of a microelectronic structure comprising a microelectronic substrate having a plurality of microelectronic die stacked thereon, according to an embodiment of the present description.

FIG. 2 illustrates a side cross-sectional view of a microelectronic structure along line 2-2 of FIG. 1, according to one embodiment of the present description.

FIG. 3 illustrates an oblique view of the microelectronic structure of FIG. 1, wherein bond wires connect signal lines of the microelectronic dice and the microelectronic substrate, according to another embodiment of the present description.

FIG. 4 illustrates a side cross-sectional view of the microelectronic structure along line 4-4 of FIG. 3, according to one embodiment of the present description.

FIG. 5 illustrates a side cross-sectional view of the microelectronic structure of FIG. 4 after the deposition of a dielectric material layer, according to one embodiment of the present description.

FIG. 6 illustrates a side cross-sectional view of the microelectronic structure along line 6-6 of FIG. 3 after the deposition of the dielectric material layer, according to one embodiment of the present description.

FIG. 7 illustrates a side cross-sectional view of the microelectronic structure of FIG. 6 after the formation of openings in to dielectric material layer to expose at least a portion of each of the ground bond pads for the microelectronic dice and the microelectronic substrate, according to one embodiment of the present description.

FIG. 8 illustrates a side cross-sectional view of the microelectronic structure of FIG. 5 after the deposition of an electrically conductive material layer on the dielectric material layer, according to one embodiment of the present description.

FIG. 9 illustrates a side cross-sectional view of the microelectronic structure of FIG. 7 after the deposition of the electrically conductive material layer on the dielectric material layer, according to one embodiment of the present description.

FIG. 10 illustrates a cross-sectional view of the bond wire, the dielectric material layer, and the electrically conductive material layer along line A-A of FIG. 8, according to one embodiment of the present description.

FIG. 11 is a flow diagram of a process of fabricating a microelectronic structure, according to an embodiment of the present description.

FIG. 12 illustrates a computing device or electronic system in accordance with one implementation of the present description.

### DESCRIPTION OF EMBODIMENTS

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

Embodiments of the present description may include a microelectronic structure or device having at least one microelectronic die attached to a microelectronic substrate, wherein a ground shielding layer is formed over the microelectronic die and the microelectronic substrate. In one embodiment, both the microelectronic substrate and the first microelectronic die may have a signal bond pad and a ground bond pad. The first microelectronic die may have an active surface and an opposing back surface and may be attached by its back surface to the microelectronic substrate. A bond wire may be used to form a connection between the signal bond pad of the microelectronic substrate and the signal bond pad of the first microelectronic die. A dielectric material layer may be formed on the microelectronic substrate and the first microelectronic die, and an electrically conductive material layer may be formed on the dielectric material layer, wherein the electrically conductive material layer extends through openings in the dielectric material layer to contact the ground bond pad of the microelectronic substrate and the ground bond pad of the first microelectronic die.

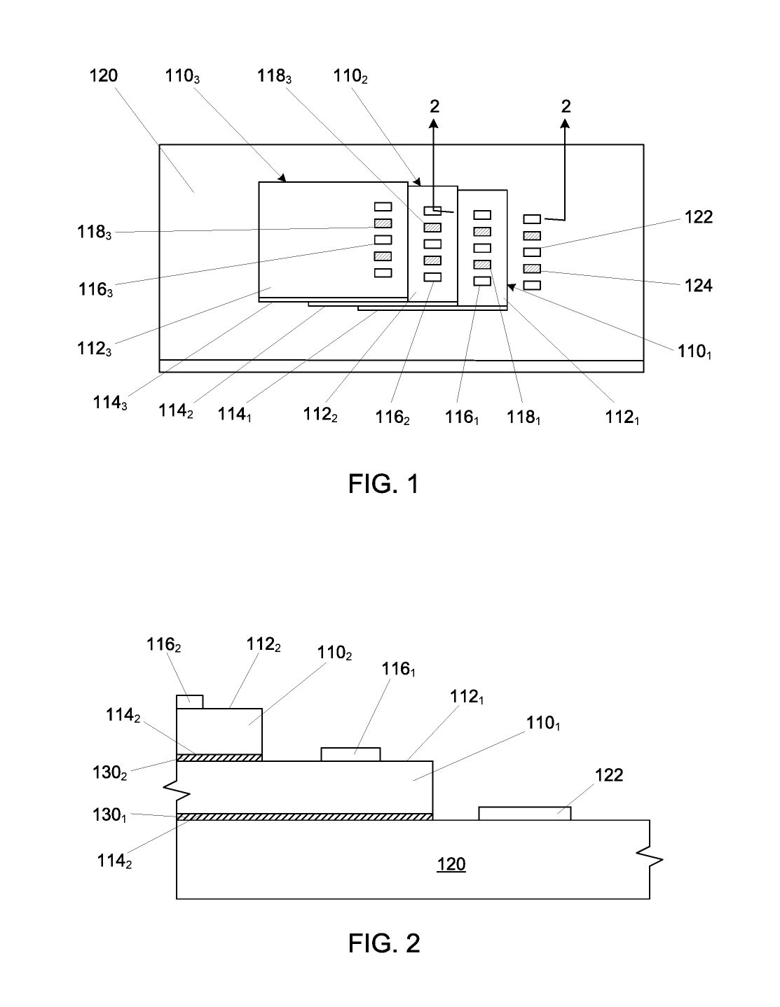

FIGS. 1-10 illustrate a process of fabricating a microelectronic structure or device. As illustrated in FIG. 1, at least one microelectronic die, such as a first microelectronic die 110₁, a second microelectronic die 110₂, and the third microelectronic die 110₃, may be stacked on a microelectronic substrate 120. The microelectronic substrate 120 may have at least one signal bond pad 122 and at least one ground bond pad 124 (shown as shaded for clarity). The microelectronic substrate signal bond pads 122 and microelectronic substrate ground bond pads 124 may be in electrical communication with conductive routes (not shown) within the microelectronic substrate 120. These microelectronic substrate conductive routes (not shown) may provide electrical communication routes to external components (not shown).

The microelectronic substrate 120 may comprise any appropriate dielectric material layer, including, but not limited to, liquid crystal polymer, epoxy resin, bismaleimide triazine resin, FR4, polyimide materials, and the like, and may include conductive routes (not shown) formed therein and/or thereon to form any desired electrical route within the microelectronic substrate 120.

The first microelectronic die 110₁, the second microelectronic die 110₂, and/or the third microelectronic die 110₃, may be any appropriate microelectronic device, including, but not limited to, microprocessors, chipsets, graphics devices, wireless devices, memory devices, application specific integrated circuit devices, and the like. In a specific embodiment, the first microelectronic die 110₁, the second microelectronic die 110₂, and/or the third microelectronic die 110₃, may be non-volatile memory devices.

The first microelectronic die 110₁ may be attached to the microelectronic substrate 120 proximate to the microelectronic substrate signal bond pads 122 and the microelectronic substrate ground bond pads 124 by its back surface 114₁. An active surface 112₁ of the first microelectronic die 110₁ may have at least one signal bond pad 116₁ and at least one ground bond pad 118₁ (shown as shaded for clarity) formed thereon or therein. The first microelectronic die signal bond pads 116₁ and the first microelectronic die ground bond pads 118₁ may be in electrical communication with integrated circuitry (not shown) within the first microelectronic die 110₁.

The second microelectronic die 110₂ may be attached to the first microelectronic die active surface 112₁ proximate to the first microelectronic die signal bond pads 116₁ and the first microelectronic die ground bond pads 118₁ by its back surface 114₂. An active surface 112₂ of the second microelectronic die 110₂ may have at least one signal bond pad 116₂ and at least one ground bond pad 118₂ (shown as shaded for clarity) formed thereon or therein. The second microelectronic die signal bond pads 116₂ and the second microelectronic die ground bond pads 118₂ may be in electrical communication with integrated circuitry (not shown) within the second microelectronic die 110₂.

The third microelectronic die 110₃ may be attached to the second microelectronic die active surface 112₂ proximate to the second microelectronic die signal bond pads 114₂ and the first microelectronic die ground bond pads 116₂ by its back surface 114₃. An active surface 112₃ of the third microelectronic die 110₃ may have at least one signal bond pad 116₃ and at least one ground bond pad 118₃ (shown as shaded for clarity) formed thereon or therein. The third microelectronic die signal bond pads 116₃ and the third microelectronic die ground bond pads 118₃ may be in electrical communication with integrated circuitry (not shown) within the third microelectronic die 110₃.

As shown, the first microelectronic die 110₁, the second microelectronic die 110₂, and the third microelectronic die 110₃ may be staggered to allow access to all of the bond pads. It is, of course, understood that the microelectronic dice may be oriented in any appropriate manner to allow access to various bond pads.

In one embodiment of the present description, adhesive layers may be used to stack the microelectronic dice. For example, as shown in FIG. 2, a first adhesive layer 130₁ may attach the first microelectronic die back surface 114₁ to the microelectronic substrate 120 and a second adhesive layer 130₂ may attach the second microelectronic die back surface 114₂ to the first microelectronic die active surface 112₁.

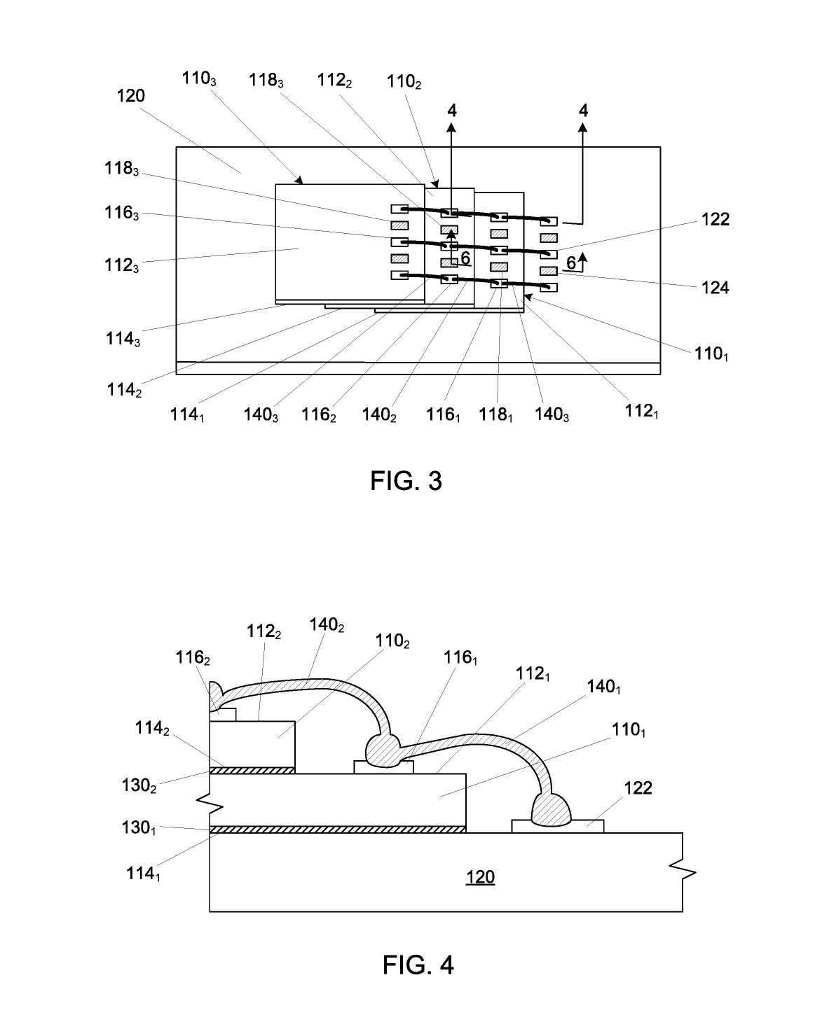

As shown in FIGS. 3 and 4, bond wires may be attached between the signal bond pads of the microelectronic dice and the microelectronic substrate. As shown, the microelectronic substrate signal bond pads 122 may be connected to respective first microelectronic die signal bond pads 112₁ with first level bond wires 140₁, the first microelectronic die signal bond pads 112₁ may be connected to respective second microelectronic die signal bond pads 112₂ with second level bond wires 140₂, and the second microelectronic die signal bond pads 112₂ may be connected to respective third microelectronic die signal bond pads 112₃ with third level bond wires 140₃. It is understood that embodiments of the present description are not limited to any particular number of stacked microelectronic dice, nor limited to any specific bond wire arrangement or attachment configuration.

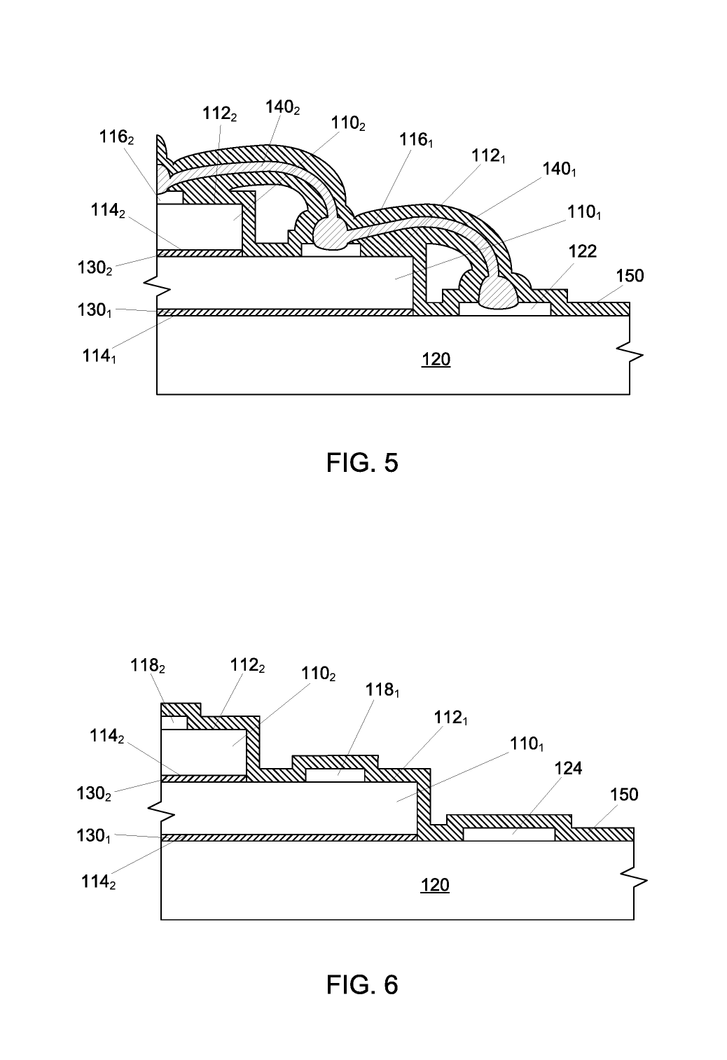

A dielectric material layer 150 may be deposited over at least of portion of each of the microelectronic dice 110₁, 110₂, 110₃ and the microelectronic substrate 120. As shown in FIG. 5, the deposition of the dielectric material layer 150 may encapsulate each of the bond wires (shown as first level bond wire 140₁ and second level bond wire 140₂). As shown in FIG. 6 (a cross-section in the position of line 6-6 of FIG. 3), the deposition of the dielectric material layer 150 may cover the ground bond pads (shown as the microelectronic substrate ground bond pads 124, the first microelectronic die ground bond pads 118₁, and the second microelectronic die ground bond pads 118₂). In one embodiment, the dielectric material layer 150 may be substantially conformally deposited.

The dielectric material layer 150 may be any appropriate electrically insulating material, including, but not limited to, silicon dioxide, silicon oxy-nitride, or silicon nitride. In another embodiment, the dielectric material layer 150 may comprise a low-k dielectric material which may have a dielectric constant less than 3.6. The dielectric material layer 150 may be deposited in any manner known in the art, including but not limited sputtering and chemical vapor deposition.

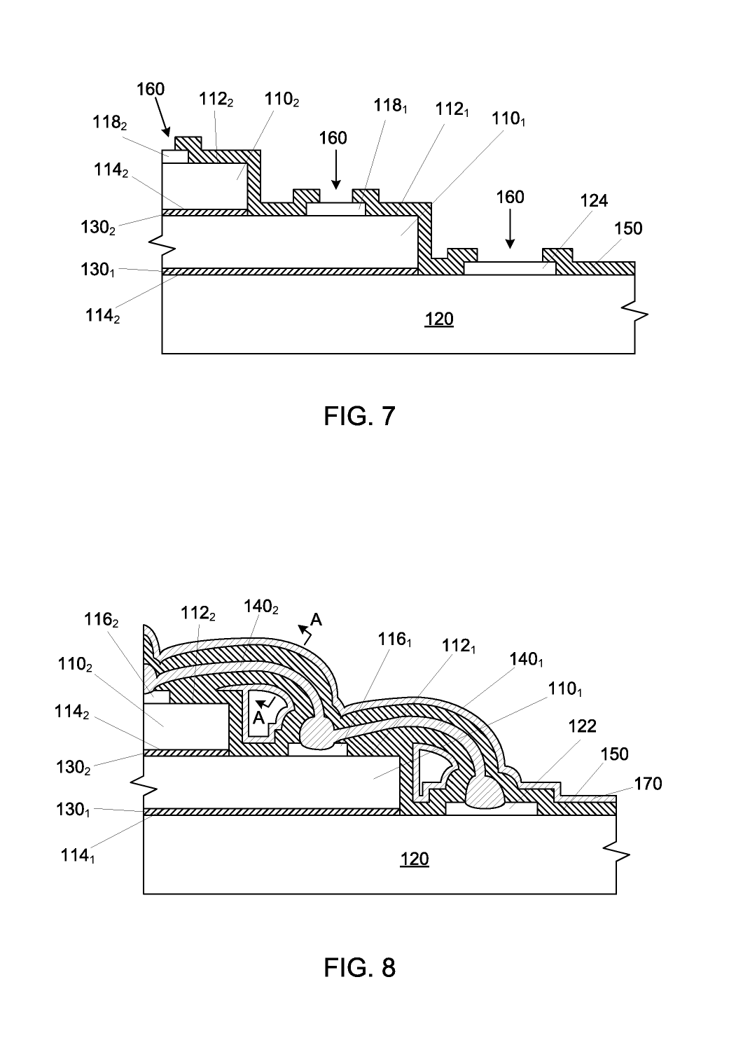

As shown in FIG. 7, openings 160 may be formed through the dielectric material layer 150 to expose at least a portion each of the ground bond pads (shown as the microelectronic substrate ground bond pads 124, the first microelectronic die ground bond pads 118₁, and the second microelectronic die ground bond pads 118₂). The openings 160 may be formed by any technique known in the art, including, but not limited to, etching, ion ablation, laser ablation, and the like.

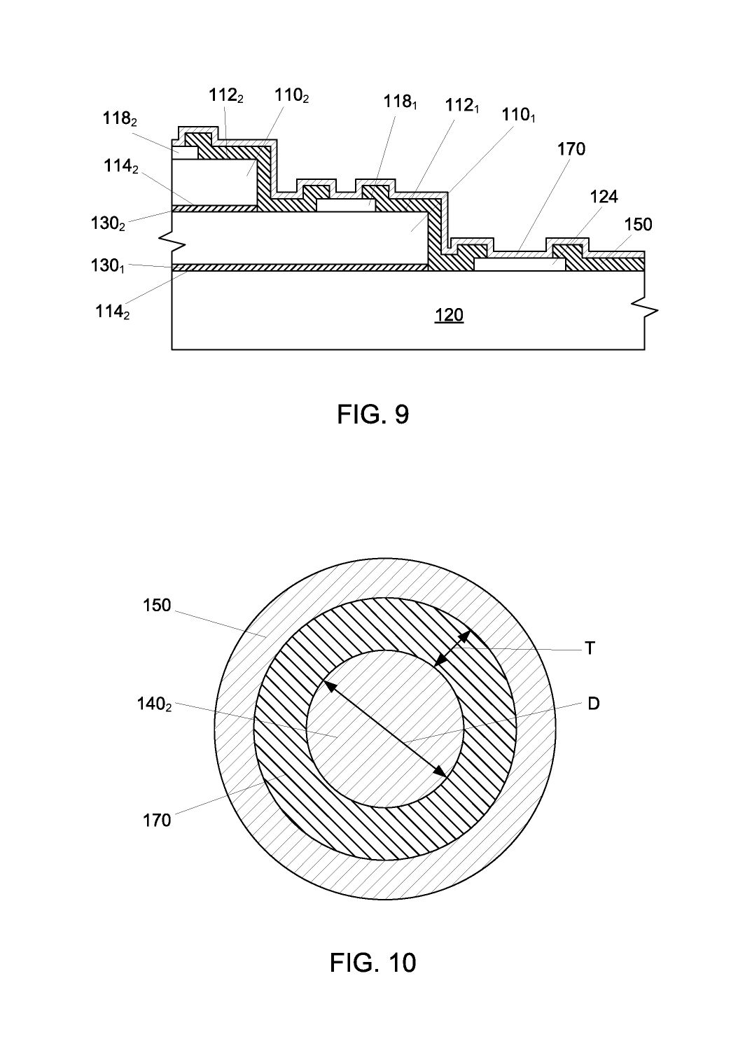

An electrically conductive material layer 170 may be deposited over the dielectric material layer 150. As shown in FIG. 8, the deposition of the electrically conductive material layer 170 may further encapsulate each of the bond wires (shown as first level bond wire 140₁ and second level bond wire 140₂). As shown in FIG. 9, the electrically conductive material layer 170 may contact the ground bond pads (shown as the substrate ground bond pads 124, the first microelectronic die ground bond pads 118₁, and the second microelectronic die ground bond pads 118₂). As will be understood, the contact of the electrically conductive material layer 170 to the ground bond pads (e.g. the substrate ground bond pads 124 and the microelectronic die ground bond pads 118₁, 118₂, and 118₃) shorts them together to effectively forming a conductor shielding coating.

The electrically conductive material layer 170 may be any appropriate conductive material, including, but not limited to, copper, gold, silver, nickel, aluminum, alloy thereof, and the like. The electrically conductive material layer 170 may be deposited in any manner known in the art, including but not limited sputtering and chemical vapor deposition. In one embodiment, the electrically conductive material layer 170 may be substantially conformally deposited.

As shown in FIG. 10 (a cross-section along line A-A of FIG. 8), at least a portion of each of the bond wires (shown as first level bond wire 140₂) may effectively be a coaxial connector. Thus, the impedance of the connection made by the bond wires can be controlled by manipulating the diameter D of the bond wire (shown as first level bond wire 140₂), the thickness T of the dielectric material layer 150, as well as the dielectric constant of the dielectric material layer 150, as will be understood to those skilled in the art.

Embodiments of the present description may results in the interconnections formed by the bond wires 140₁, 140₂, and 140₃ having return paths and impedance control to prevent noise from discontinuities. The electrically conductive material layer 170 substantially surrounding the bond wires 140₁, 140₂, and 140₃ may contain the magnetic fields the can result in cross-talk. The improvement in signal integrity properties may enable the use of longer bond wires 140₁, 140₂, and 140₃, which may introduce more degrees of freedom in difficult designs.

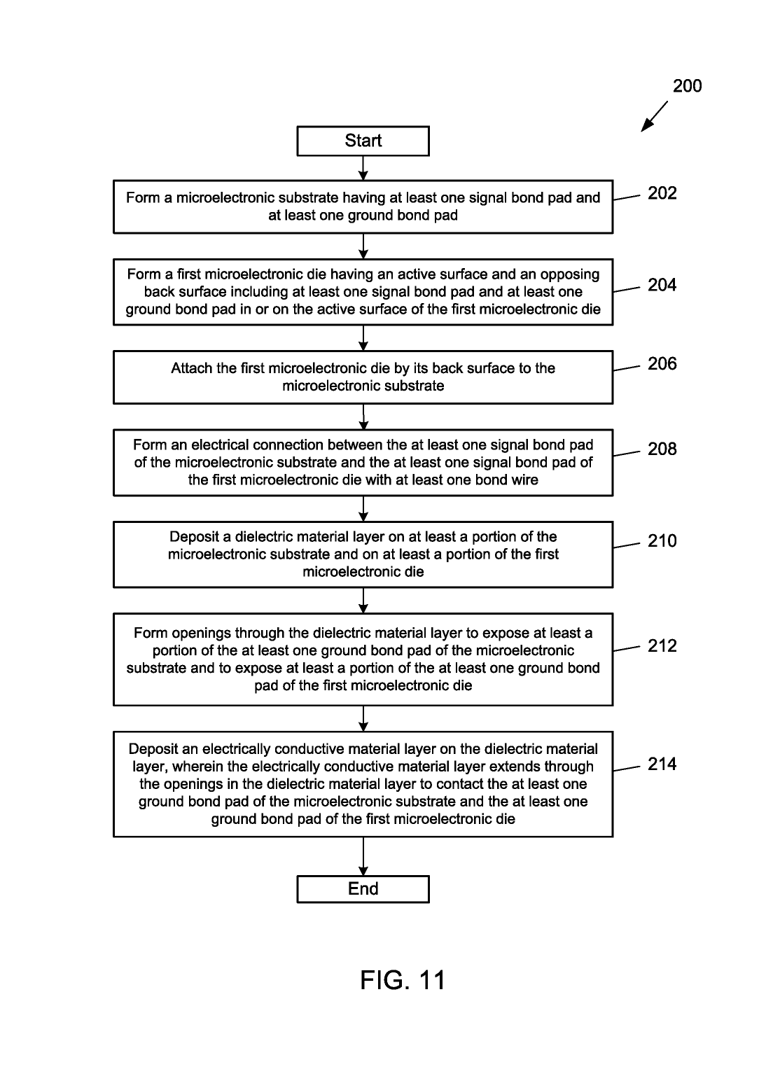

FIG. 11 is a flow chart of a process 200 of fabricating a microelectronic structure according to an embodiment of the present description. As set forth in block 202, a microelectronic substrate having at least one signal bond pad and at least one ground bond pad may be formed. A first microelectronic die may be formed having an active surface and an opposing back surface including at least one signal bond pad and at least one ground bond pad in or on the active surface of the first microelectronic die, as set forth in block 204. As set forth in block 206, the first microelectronic die may be attached by its back surface to the microelectronic substrate. An electrical connection may be formed between the at least one signal bond pad of the microelectronic substrate and the at least one signal bond pad of the first microelectronic die with at least one bond wire, as set forth in block 208. As set forth in block 210, a dielectric material layer may be deposited on at least a portion of the microelectronic substrate and on at least a portion of the first microelectronic die. Openings may be formed through the dielectric material layer to expose at least a portion of the at least one ground bond pad of the microelectronic substrate and to expose at least a portion of the at least one ground bond pad of the first microelectronic die, as set forth in block 212. At set forth in block 214, an electrically conductive material layer may be deposited on the dielectric material layer, wherein the electrically conductive material layer extends through the openings in the dielectric material layer to contact the at least one ground bond pad of the microelectronic substrate and the at least one ground bond pad of the first microelectronic die.

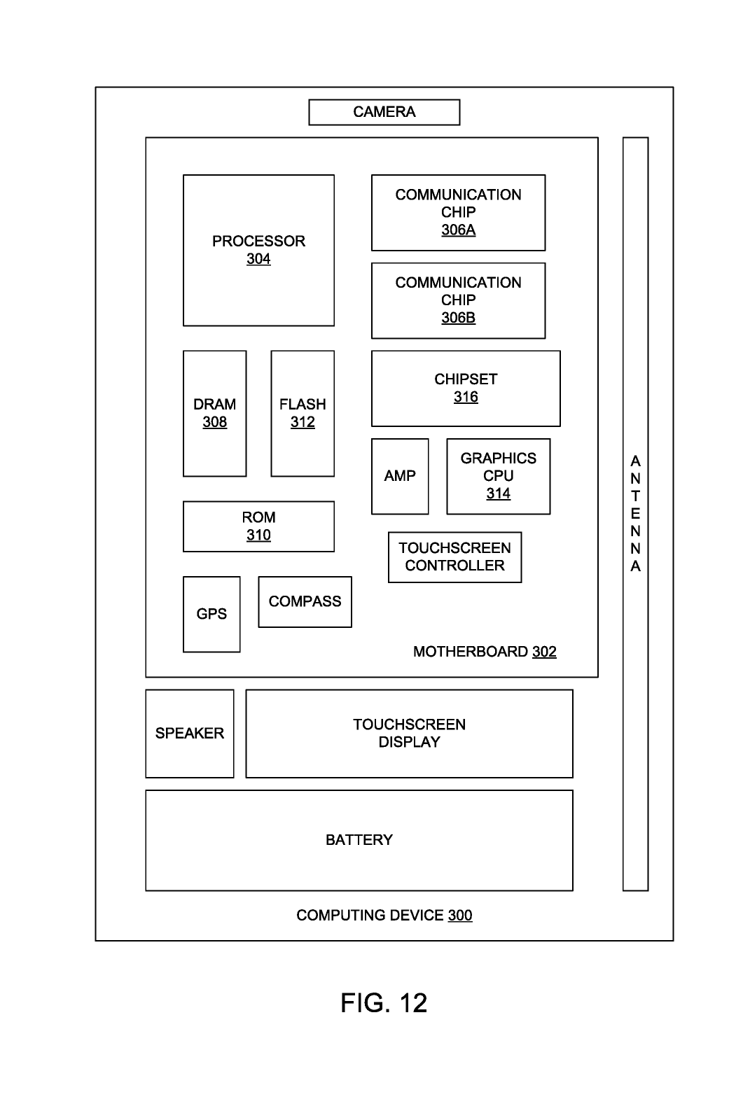

FIG. 12 illustrates a computing device or electrical system 300 in accordance with one implementation of the present description. The computing device or electrical system 300 houses a board 302. The board may include a number of microelectronic components, including but not limited to a processor 304, at least one communication chip 306A, 306B, volatile memory 308, (e.g., DRAM), non-volatile memory 310 (e.g., ROM), flash memory 312, a graphics processor or CPU 314, a digital signal processor (not shown), a crypto processor (not shown), a chipset 316, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker (not shown), a camera, and a mass storage device (not shown) (such as hard disk drive, compact disk (CD), digital versatile disk (DVD), and so forth). Any of the microelectronic components may be physically and electrically coupled to the board 302. In some implementations, at least one of the microelectronic components may be a part of the processor 304.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

Any of the microelectronic components within the computing device 300 may include a microelectronic structure having a microelectronic die stack attached to microelectronic substrate, wherein signals bond pads of the microelectronic die stack and the microelectronic may be connected with wire bonds and wherein ground bond pads of the microelectronic die stack and the microelectronic substrate are connected with an electrically conductive material layer.

In various implementations, the computing device may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-12. The subject matter may be applied to other microelectronic devices and assembly applications, as well as any appropriate electronic application, as will be understood to those skilled in the art.

The follow examples pertain to further embodiments and specifics in the examples may be used anywhere in one or more embodiments, wherein Example 1 is a microelectronic structure, comprising a microelectronic substrate have at least one signal bond pad and at least one ground bond pad, a first microelectronic die having an active surface and an opposing back surface attached by its back surface to the microelectronic substrate, wherein the first microelectronic die includes at least one signal bond pad and at least one ground bond pad in or on the first microelectronic die active surface, at least one first level bond wire forming a connection between the at least one signal bond pad of the microelectronic substrate and the at least one signal bond pad of the first microelectronic die, a dielectric material layer formed on at least a portion of the microelectronic substrate and on at least a portion of the first microelectronic die; and an electrically conductive material layer formed on the dielectric material layer wherein the electrically conductive material layer extends through openings in the dielectric material layer to contact the at least one ground bond pad of the microelectronic substrate and the at least one ground bond pad of the first microelectronic die.

In Example 2, the subject matter of Example 1 can optionally include the dielectric material layer being conformally formed on the microelectronic substrate and the first microelectronic die.

In Example 3, the subject matter of any of Examples 1 and 2 can optionally include the electrically conductive material layer being conformally formed on the dielectric material layer.

In Example 4, the subject matter of any of Examples 1 to 3 can optionally include the dielectric material layer and the electrically conductive material layer being in a substantially co-axial orientation to at least a portion of the at least one first level bond wire.

In Example 5, the subject matter of any of Examples 1 to 4 can optionally include the dielectric material layer being selected from the group consisting of silicon dioxide, silicon oxy-nitride, silicon nitride, and low-k dielectric materials.

In Example 6, the subject matter of any of Examples 1 to 5 can optionally include the electrically conductive material layer being selected from the group consisting of copper, gold, silver, nickel, aluminum, and alloys thereof.

In Example 7, the subject matter of any of Examples 1 to 6 can optionally include a second microelectronic die having an active surface and an opposing back surface attached by its back surface to the active surface of the first microelectronic die, wherein the second microelectronic die includes at least one signal bond pad and at least one ground bond pad in or on the second microelectronic die active surface; and at least one second level bond wire forming a connection between the at least one signal bond pad of the first microelectronic die and the at least one signal bond pad of the second microelectronic die.

In Example 8, a method of fabricating a microelectronic structure may comprise forming a microelectronic substrate having at least one signal bond pad and at least one ground bond pad, forming a first microelectronic die having an active surface and an opposing back surface including at least one signal bond pad and at least one ground bond pad in or on the active surface of the first microelectronic die, attaching the first microelectronic die by its back surface to the microelectronic substrate, forming an electrical connection between the at least one signal bond pad of the microelectronic substrate and the at least one signal bond pad of the first microelectronic die with at least one bond wire, depositing a dielectric material layer on at least a portion of the microelectronic substrate and on at least a portion of the first microelectronic die, forming openings through the dielectric material layer to expose at least a portion of the at least one ground bond pad of the microelectronic substrate and to expose at least a portion of the at least one ground bond pad of the first microelectronic die; and depositing an electrically conductive material layer on the dielectric material layer, wherein the electrically conductive material layer extends through the openings in the dielectric material layer to contact the at least one ground bond pad of the microelectronic substrate and the at least one ground bond pad of the first microelectronic die.

In Example 9, the subject matter of Example 8 can optionally include depositing the dielectric material layer comprising conformally depositing the dielectric material layer on the microelectronic substrate and the first microelectronic die.

In Example 10, the subject matter of any of Examples 8 and 9 can optionally include depositing the electrically conductive material layer comprising conformally depositing the electrically conductive material layer on the dielectric material layer.

In Example 11, the subject matter of any of Examples 8 to 10 can optionally include depositing the dielectric material layer and depositing the electrically conductive material layer comprises depositing the dielectric material layer and depositing the electrically conductive material layer in a substantially co-axial orientation to at least a portion of the at least one first level bond wire.

In Example 12, the subject matter of any of Examples 8 to 11 can optionally include depositing the dielectric material layer comprises depositing a dielectric material selected from the group consisting of silicon dioxide, silicon oxy-nitride, silicon nitride, and low-k dielectric materials.

In Example 13, the subject matter of any of Examples 8 to 12 can optionally include depositing the electrically conductive material layer comprises depositing an electrically conductive material selected from the group consisting of copper, gold, silver, nickel, aluminum, and alloys thereof.

In Example 14, the subject matter of any of Examples 8 to 13 can optionally include forming openings through the dielectric material layer comprises forming openings a technique selected from the group consisting of etching, ion ablation, and laser ablation.

In Example 15, the subject matter of any of Examples 9 to 14 can optionally include including forming a second microelectronic die having an active surface and an opposing back surface attached by its back surface to the active surface of the first microelectronic die, wherein the second microelectronic die includes at least one signal bond pad and at least one ground bond pad in or on the second microelectronic die active surface; and forming a connection between the at least one signal bond pad of the first microelectronic die and the at least one signal bond pad of the second microelectronic die with at least one second level bond wire.

In Example 16, an electronic system may comprise a board; and a microelectronic package attached to the board, wherein the microelectronic package includes a microelectronic substrate have at least one signal bond pad and at least one ground bond pad, a first microelectronic die having an active surface and an opposing back surface attached by its back surface to the microelectronic substrate, wherein the first microelectronic die includes at least one signal bond pad and at least one ground bond pad in or on the first microelectronic die active surface, at least one first level bond wire forming a connection between the at least one signal bond pad of the microelectronic substrate and the at least one signal bond pad of the first microelectronic die, a dielectric material layer formed on at least a portion of the microelectronic substrate and on at least a portion of the first microelectronic die, and an electrically conductive material layer formed on the dielectric material layer wherein the electrically conductive material layer extends through openings in the dielectric material layer to contact the at least one ground bond pad of the microelectronic substrate and the at least one ground bond pad of the first microelectronic die.

In Example 17, the subject matter of Example 16 can optionally include the dielectric material layer being conformally formed on the microelectronic substrate and the first microelectronic die.

In Example 18, the subject matter of any of Examples 16 and 17 can optionally include the electrically conductive material layer being conformally formed on the dielectric material layer.

In Example 19, the subject matter of any of Examples 16 to 18 can optionally include the dielectric material layer and the electrically conductive material layer being in a substantially co-axial orientation to at least a portion of the at least one first level bond wire.

In Example 20, the subject matter of any of Examples 16 to 19 can optionally include the dielectric material layer being selected from the group consisting of silicon dioxide, silicon oxy-nitride, silicon nitride, and low-k dielectric materials.

In Example 21, the subject matter of any of Examples 16 to 20 can optionally include the electrically conductive material layer being selected from the group consisting of copper, gold, silver, nickel, aluminum, and alloys thereof.

In Example 22, the subject matter of any of Examples 16 to 21 can optionally include a second microelectronic die having an active surface and an opposing back surface attached by its back surface to the active surface of the first microelectronic die, wherein the second microelectronic die includes at least one signal bond pad and at least one ground bond pad in or on the second microelectronic die active surface; and at least one second level bond wire forming a connection between the at least one signal bond pad of the first microelectronic die and the at least one signal bond pad of the second microelectronic die.

Having thus described in detail embodiments of the present description, it is understood that the present description defined by the appended claims is not to be limited by particular details set forth in the above description, as many apparent variations thereof are possible without departing from the spirit or scope thereof.

1-22. (canceled)

23. A microelectronic structure, comprising:
a microelectronic substrate have at least one signal bond pad and at least one ground bond pad;
a first microelectronic die having an active surface and an opposing back surface attached by its back surface to the microelectronic substrate, wherein the first microelectronic die includes at least one signal bond pad and at least one ground bond pad in or on the first microelectronic die active surface;
at least one first level bond wire forming a connection between the at least one signal bond pad of the microelectronic substrate and the at least one signal bond pad of the first microelectronic die;
a dielectric material layer formed on at least a portion of the microelectronic substrate and on at least a portion of the first microelectronic die; and
an electrically conductive material layer formed on the dielectric material layer wherein the electrically conductive material layer extends through openings in the dielectric material layer to contact the at least one ground bond pad of the microelectronic substrate and the at least one ground bond pad of the first microelectronic die.

24. The microelectronic structure of claim 1, wherein the dielectric material layer is conformally formed on the microelectronic substrate and the first microelectronic die.

25. The microelectronic structure of claim 1, wherein the electrically conductive material layer is conformally formed on the dielectric material layer.

26. The microelectronic structure of claim 1, wherein the dielectric material layer and the electrically conductive material layer are in a substantially co-axial orientation to at least a portion of the at least one first level bond wire.

27. The microelectronic structure of claim 1, wherein the dielectric material layer is selected from the group consisting of silicon dioxide, silicon oxy-nitride, silicon nitride, and low-k dielectric materials.

28. The microelectronic structure of claim 1, wherein the electrically conductive material layer is selected from the group consisting of copper, gold, silver, nickel, aluminum, and alloys thereof.

29. The microelectronic structure of claim 1, further including a second microelectronic die having an active surface and an opposing back surface attached by its back surface to the active surface of the first microelectronic die, wherein the second microelectronic die includes at least one signal bond pad and at least one ground bond pad in or on the second microelectronic die active surface; and at least one second level bond wire forming a connection between the at least one signal bond pad of the first microelectronic die and the at least one signal bond pad of the second microelectronic die.

30. A method of fabricating a microelectronic structure, comprising:
forming a microelectronic substrate having at least one signal bond pad and at least one ground bond pad;
forming a first microelectronic die having an active surface and an opposing back surface including at least one signal bond pad and at least one ground bond pad in or on the active surface of the first microelectronic die;
attaching the first microelectronic die by its back surface to the microelectronic substrate;
forming an electrical connection between the at least one signal bond pad of the microelectronic substrate and the at least one signal bond pad of the first microelectronic die with at least one bond wire;
depositing a dielectric material layer on at least a portion of the microelectronic substrate and on at least a portion of the first microelectronic die;
forming openings through the dielectric material layer to expose at least a portion of the at least one ground bond pad of the microelectronic substrate and to expose at least a portion of the at least one ground bond pad of the first microelectronic die; and
depositing an electrically conductive material layer on the dielectric material layer, wherein the electrically conductive material layer extends through the openings in the dielectric material layer to contact the at least one ground bond pad of the microelectronic substrate and the at least one ground bond pad of the first microelectronic die.

31. The method of claim 30, wherein depositing the dielectric material layer comprises conformally depositing the dielectric material layer on the microelectronic substrate and the first microelectronic die.

32. The method of claim 30, wherein depositing the electrically conductive material layer comprises conformally depositing the electrically conductive material layer on the dielectric material layer.

33. The method of claim 30, wherein depositing the dielectric material layer and depositing the electrically conductive material layer comprises depositing the dielectric material layer and depositing the electrically conductive material layer in a substantially co-axial orientation to at least a portion of the at least one first level bond wire.

34. The method of claim 30, wherein depositing the dielectric material layer comprises depositing a dielectric material selected from the group consisting of silicon dioxide, silicon oxy-nitride, silicon nitride, and low-k dielectric materials.

35. The method of claim 30, wherein depositing the electrically conductive material layer comprises depositing an electrically conductive material selected from the group consisting of copper, gold, silver, nickel, aluminum, and alloys thereof.

36. The method of claim 30, wherein forming openings through the dielectric material layer comprises forming openings a technique selected from the group consisting of etching, ion ablation, and laser ablation.

37. The method of claim 30, further including forming a second microelectronic die having an active surface and an opposing back surface attached by its back surface to the active surface of the first microelectronic die, wherein the second microelectronic die includes at least one signal bond pad and at least one ground bond pad in or on the second microelectronic die active surface; and forming a connection between the at least one signal bond pad of the first microelectronic die and the at least one signal bond pad of the second microelectronic die with at least one second level bond wire.

38. An electronic system, comprising:
a board; and
a microelectronic package attached to the board, wherein the microelectronic package includes:
a microelectronic substrate have at least one signal bond pad and at least one ground bond pad;
a first microelectronic die having an active surface and an opposing back surface attached by its back surface to the microelectronic substrate, wherein the first microelectronic die includes at least one signal bond pad and at least one ground bond pad in or on the first microelectronic die active surface;
at least one first level bond wire forming a connection between the at least one signal bond pad of the microelectronic substrate and the at least one signal bond pad of the first microelectronic die;
a dielectric material layer formed on at least a portion of the microelectronic substrate and on at least a portion of the first microelectronic die; and
an electrically conductive material layer formed on the dielectric material layer wherein the electrically conductive material layer extends through openings in the dielectric material layer to contact the at least one ground bond pad of the microelectronic substrate and the at least one ground bond pad of the first microelectronic die.

39. The electronic system of claim 38, wherein the dielectric material layer is conformally formed on the microelectronic substrate and the first microelectronic die.

40. The electronic system of claim 38, wherein the electrically conductive material layer is conformally formed on the dielectric material layer.

41. The electronic system of claim 38, wherein the dielectric material layer and the electrically conductive material layer are in a substantially co-axial orientation to at least a portion of the at least one first level bond wire.

42. The electronic system of claim 38, wherein the dielectric material layer is selected from the group consisting of silicon dioxide, silicon oxy-nitride, silicon nitride, and low-k dielectric materials.

43. The electronic system of claim 38, wherein the electrically conductive material layer is selected from the group consisting of copper, gold, silver, nickel, aluminum, and alloys thereof.

44. The electronic system of claim 38, further including a second microelectronic die having an active surface and an opposing back surface attached by its back surface to the active surface of the first microelectronic die, wherein the second microelectronic die includes at least one signal bond pad and at least one ground bond pad in or on the second microelectronic die active surface; and at least one second level bond wire forming a connection between the at least one signal bond pad of the first microelectronic die and the at least one signal bond pad of the second microelectronic die.
